(19) United States
(12) Patent Application Publication
(10) Pub. No.: US 2023/0352489 A1
(43) Pub. Date: Nov. 2, 2023

(54) DISPLAY PANEL AND DISPLAY DEVICE

(71) Applicant: Wuhan China Star Optoelectronics Technology Co., Ltd., Wuhan (CN)

(72) Inventors: Lixin ZHANG, Wuhan (CN); Chao WANG, Wuhan (CN); Guanghui LIU, Wuhan (CN)

(21) Appl. No.: 17/278,690

(22) PCT Filed: Jan. 21, 2021
(86) PCT No.: PCT/CN2021/073082

§ 371 Date: Mar. 23, 2021

(30) Foreign Application Priority Data
Dec. 30, 2020 (CN) 202011642959.7

(51) Int. Cl. H01L 27/12; G02F 1/1368; G02F 1/1362

(52) U.S. Cl. CPC H01L 27/1222; G02F 1/1368; G02F 1/136209

(57) ABSTRACT

A display panel and a display device are provided. The display panel includes a transistor, and the transistor includes an active layer extending in a second direction and a gate layer located on one side of the active layer. The gate layer includes a main stem portion extending in a first direction and a branch portion extending from a side of the main stem portion. In a top view, the active layer overlaps the main stem portion and the branch portion to realize a multiple gate design, optimize layout of the transistor, and facilitate increasing an aperture ratio of a pixel and realizing a sensing integration design.

### FIELD OF INVENTION

The present application relates to the field of display technology, and especially to a display panel and a display device.

### BACKGROUND OF INVENTION

As shown in FIG. 1, in a conventional display device, thin film transistors (TFTs) used in a pixel driving circuit often adopt a U-shaped double gate TFT design. However, the U-shaped double gate TFT design occupies a larger area and affects an aperture ratio of a pixel, and it is also inappropriate in designs such as integrating a sensing technology into a display device.

### SUMMARY OF INVENTION

Embodiments of the present application provide a display panel and a display device that can mitigate influence on an aperture ratio of a pixel caused by transistors, facilitating realization of designs of integrating a sensing technology into a display device.

Embodiments of the present application provide a display panel that includes a transistor, and the transistor includes an active layer and a gate layer. The active layer extends in a second direction, the gate layer is located on one side of the active layer, and the gate layer includes a main stem portion extending in a first direction and a branch portion extending from a side of the main portion. Wherein, in a top view, the active layer overlaps the main stem portion and the branch portion at an overlapping area.

In some embodiments, the branch portion includes a first branch portion and a second branch portion. The first branch portion extends from the side of the main stem portion in a direction away from the main stem portion, and the second branch portion extends from one end of the first branch portion away from the main stem portion in a direction away from the first branch portion. Wherein, the second branch portion overlaps the active layer at the overlapping area.

In some embodiments, the second branch portion is parallel to the main stem portion.

In some embodiments, a distance between the second branch portion and the main stem portion is greater than 3 micrometers.

In some embodiments, the display panel further includes a plurality of the transistors, wherein a plurality of the active layers of the plurality of the transistors are spaced along the first direction, a plurality of the branch portions of the gate layer of the plurality of the transistors are spaced from one another, the main stem portion overlaps the active layers of the plurality of the transistors at the overlapping area, and the branch portion of each of the plurality of the transistors correspondingly overlaps the active layers at the overlapping area.

In some embodiments, the display panel further includes a shading layer located on one side of the active layer away from the gate layer, and the shading layer includes a shading portion and a wiring portion. Wherein, the shading portion corresponds to the active layer, and the wiring portion is electrically connected to the active layer.

In some embodiments, the display panel further includes a second electrode layer and a third electrode layer. The active layer is electrically connected to the wiring portion through the second electrode layer, and the third electrode layer is located on one side of the gate layer away from the active layer and electrically connected to the active layer.

In some embodiments, the display panel further includes an insulating layer, wherein the insulating layer defines a via hole, and the second electrode layer is electrically connected to the active layer through the via hole.

In some embodiments, the insulating layer includes a first insulating layer, the first insulating layer is located between the shading layer and the active layer, the first insulating layer defines the via hole, and the second electrode layer is electrically connected to the active layer and the wiring portion through the via hole in the first insulating layer.

In some embodiments, the via hole comprises a first via hole and a second via hole spaced apart, and the second electrode layer comprises a first connecting part, a second connecting part, and a third connecting part electrically connected between the first connecting part and the second connecting part, wherein, the first connecting part is in the first via hole, the first connecting part is electrically connected to the active layer, the second connecting part is in the second via hole, and the second connecting part is electrically connected to the wiring portion.

In some embodiments, in the top view, the shading portion is a rectangle or an I shape.

In some embodiments, in the top view, the active layer is a straight line shape or an I shape, and the gate layer is an h shape, a Y shape, a Σ shape, or a Z shape.

In some embodiments, the active layer includes a channel area and a doping area located on two sides of the channel area, and in the top view, a width of the doping area is greater than or equal to a width of the channel area.

The present application further provides a display device that includes any one of the above-described display panels.

In comparison with conventional technology, embodiments of the present application provide a display panel and a display device, where the display panel includes a transistor, and the transistor includes an active layer and a gate layer. The active layer extends in a second direction, the gate layer is located on one side of the active layer, and the gate layer includes a main stem portion extending in a first direction and a branch portion extending from a side of the main stem portion. Wherein, in a top view, the active layer overlaps the main stem portion and the branch portion to make a part of the gate layer corresponding to the active layer become a gate of the transistor, thereby realizing layout optimization of the transistor, and facilitating increasing an aperture ratio of a pixel and realization of a sensing technology integration design, while realizing a multiple gate design.

### DESCRIPTION OF DRAWINGS

FIG. 1 is a structural schematic diagram of a U-shaped double gate thin film transistor (TFT) design adopted in a conventional display panel.

FIG. 2A-FIG. 2H are structural schematic diagrams of a shading layer, an active layer, and a gate layer according to embodiments of the present application.

FIG. 2I is a partial enlargement diagram of the gate layer according to embodiments of the present application.

FIG. 3A-FIG. 3C are structural schematic diagrams of display panels according to embodiments of the present application.

### DETAILED DESCRIPTION OF PREFERRED EMBODIMENTS

For clearer description of purposes, technical approaches, and effects of the present application, the following further describes the present application in detail with reference to accompanying drawings and embodiments. It should be understood that the specific embodiments described here are merely for understanding the present application and are not to limit the present application.

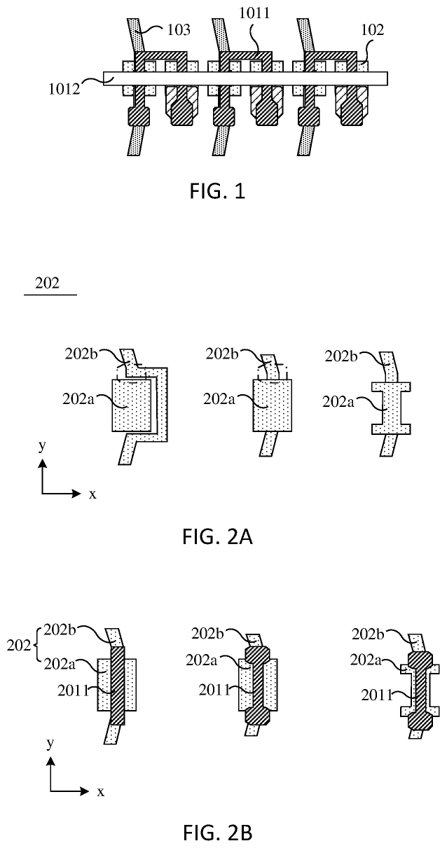

Specifically, referring to FIG. 1, FIG. 1 is a structural schematic diagram of a U-shaped double gate thin film transistor (TFT) design adopted in a conventional display panel. In a top view, an active layer 1011 is a U shape, a gate layer 1012 is a straight line shape, and the active layer 1011 and the gate layer 1012 are disposed crossing each other, so that a part of the gate layer 1012 corresponding to the active layer 1011 becomes a gate of a transistor. A shading layer 102 is disposed corresponding to the gate. A data line 103 partially overlaps the active layer 1011 to be connected to one of a source or a drain of the transistor. As can be seen from FIG. 1, the shading layer 102, the active layer 1011, and the gate layer 1012 occupy a larger area, affecting an aperture ratio of a pixel. It is inappropriate in designs such as integrating a sensing technology into a display panel.

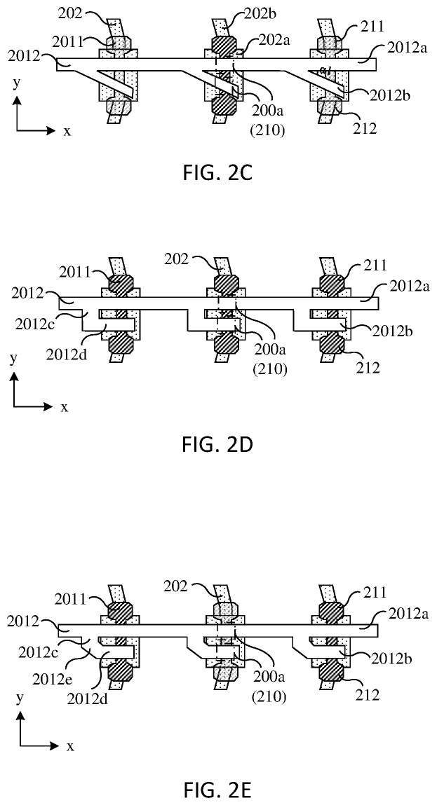

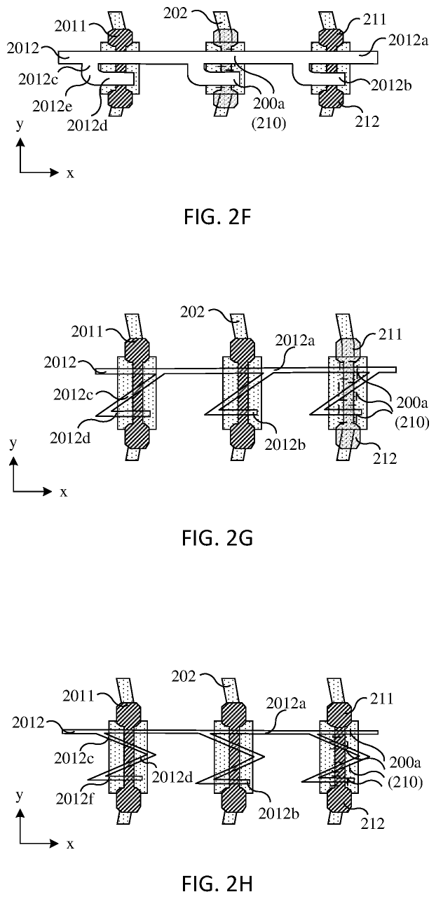

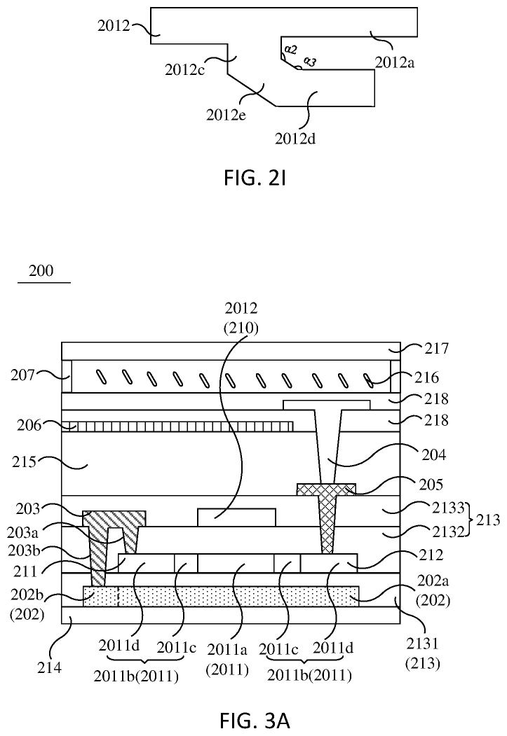

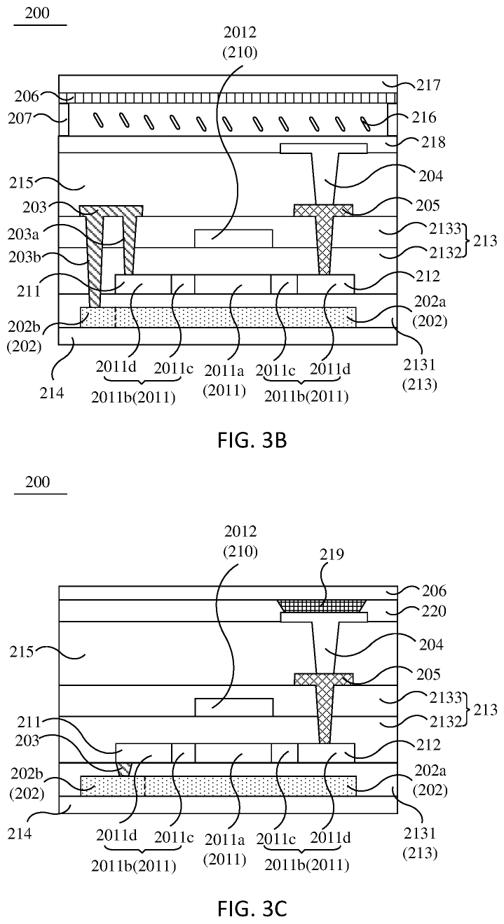

Refer to FIG. 2A-FIG. 2H, which are structural schematic diagrams of a shading layer, an active layer, and a gate layer according to embodiments of the present application. FIG. 3A-FIG. 3C are structural schematic diagrams of display panels according to embodiments of the present application. Wherein, FIG. 2A is a structural schematic diagram of the shading layer according to embodiments of the present application, FIG. 2B is a structural schematic diagram of the shading layer and the active layer according to embodiments of the present application, and FIG. 2C-FIG. 2H are structural schematic diagrams of the shading layer, the active layer, and the gate layer.

Embodiments of the present application provides a display panel 200. Optionally, the display panel 200 includes a liquid crystal display panel, a self-luminescence display panel, a quantum dot display panel, etc. Furthermore, the self-luminescence display panel includes an organic light emitting diode (OLED) display panel, a mini light emitting diode (mini LED) display panel, a micro light emitting diode (micro LED) display panel, etc.

Referring again to FIG. 2C-FIG. 2H and FIG. 3A-FIG. 3C, the display panel 200 includes a transistor. Optionally, the transistor includes a field effect transistor. Furthermore, the transistor includes a thin film transistor. Still furthermore, the transistor includes a silicon transistor and an oxide transistor.

Referring to FIG. 2C-FIG. 2H, the transistor includes an active layer 2011 and a gate layer 2012 located on one side of the active layer 2011. The active layer 2011 extends in a second direction y. The gate layer 2012 includes a main stem portion 2012a and a branch portion 2012b extending from a side of the main stem portion 2012a, the main stem portion 2012a extends in a first direction x intersecting the second direction y, and the branch portion 2012b extends from the side of the main stem portion 2012a in a direction away from the main stem portion 2012a. The main stem portion 2012a and the branch portion 2012b both overlap the active layer 2011 at an overlapping area 200a, so that a part of the main stem portion 2012a and a part of the branch portion 2012b corresponding to the active layer 2011 separately become a gate 210 of the transistor to realize a multiple gate design. Because of the active layer 2011 extending in the second direction y, an area occupied by the active layer 2011 along the first direction x is decreased, thereby realizing optimized layout of the transistor, decreasing an area occupied by the transistor, and facilitating increasing of an aperture ratio of a pixel and realization of designs such as integrating sensing technology into the display panel, while realizing a multiple gate design.

Furthermore, in a top view, the active layer 2011 is a straight line shape, an I shape, etc., and the gate layer 2012 is an h shape, a Y shape, a Σ shape, a Z shape, etc. In comparison with a U shape active layer of a conventional display panel, a design of a gate layer being a straight line shape can realize optimized layout of the transistor, and decrease a ratio of area occupied by the transistor, facilitating increasing an aperture ratio and realization of designs such as integration of sensing technology, while realizing a multiple gate design.

Specifically, referring to FIG. 2C, in the top view, the gate layer 2012 is a Y shape, the main stem portion 2012a has a first angle α1 with respect to the branch portion 2012b, and the first angle α1 is less than 90°.

Furthermore, in the top view, the gate layer 2012 is an h shape. Referring again to FIG. 2D, in order to prevent an extending length of the branch portion 2012b from being too long, causing an increased occupied area ratio of the gate layer 2012 and affecting an aperture ratio, and in order to decrease manufacturing difficulty of a connecting part between the main stem portion 2012a and the branch portion 2012b, the branch portion 2012b includes a first branch portion 2012c and a second branch portion 2012d. The first branch portion 2012c extends from the side of the main stem portion 2012a in a direction away from the main stem portion 2012a, and the second branch portion 2012d extends from one end of the first branch portion 2012c away from the main stem portion 2012a in a direction away from the first branch portion 2012c, so that the first branch portion 2012c is connected to the main stem portion 2012a, and the second branch portion 2012d is connected to the first branch portion 2012c. In the top view, the main stem portion 2012a and the second branch portion 2012d both overlap the active layer 2011 at the overlapping area 200a, and a part of the main stem portion 2012a and a part of the second branch portion 2012d that correspond to the active layer 2011 separately become the gate 210 of the transistor to realize the double gate design. Furthermore, the second branch portion 2012d is parallel to the main stem portion 2012a to decrease an occupied area ratio of the transistor.

Optionally, in the second direction y, a distance between the second branch portion 2012d and the main stem portion 2012a can be decided according to a length of a lightly doped region 2011c of the active layer 2011. Specifically, the distance between the second branch portion 2012d and the main stem portion 2012a is greater than twice the length of the lightly doped region 2011c of the active layer 2011. Furthermore, the distance between the second branch portion 2012d and the main stem portion 2012a is greater than 3 micrometers. Still furthermore, the distance between the second branch portion 2012d and the main stem portion 2012a is greater than 3.2 micrometers to ensure a satisfactory electrical and structural performance of the transistor.

Still furthermore, referring again to FIG. 2E-FIG. 2F, the branch portion 2012b further includes a third branch portion 2012e located between the first branch portion 2012c and the second branch portion 2012d, and the third branch portion 2012e is an arc shape or a straight line shape to realize a smooth connection between the first branch portion 2012c and the second branch portion 2012d. Wherein, when the third branch portion 2012e is a straight line shape, the third branch portion 2012e has a second angle α2 with respect to the first branch portion 2012c, and the third branch portion 2012e has a third angle α3 with respect to the first branch portion 2012c. Wherein, the second angle α2 and the third angle α3 are both an obtuse angle, as shown in FIG. 2I, a partial enlargement diagram of the gate layer 2012 according to embodiments of the present application.

Furthermore, in the top view, the gate layer 2012 is a Z shape. Referring to FIG. 2G, in the top view, the main stem portion 2012a, the first branch portion 2012c, and the second branch portion 2012d separately overlap the active layer 2011 at the overlapping area 200a. A part of the main stem portion 2012a, a part of the first branch portion 2012c, and a part of the second branch portion 2012d corresponding to the active layer 2011 separately become the gate 210 of the transistor to realize a multiple gate design, while decreasing an occupied area ratio of the transistor.

Still furthermore, in the top view, the gate layer 2012 is a Σ shape. Referring again to FIG. 2H, the branch portion 2012b further includes a fourth branch portion 2012f, the fourth branch portion 2012f extends from one end of the second branch portion 2012d away from the first branch portion 2012c in a direction away from the second branch portion 2012d. In the top view, the main stem portion 2012a, the first branch portion 2012c, the second branch portion 2012d, and the fourth branch portion 2012f separately overlap the active layer 2011 at the overlapping area 200a. A part of the main stem portion 2012a, a part of the first branch portion 2012c, a part of the second branch portion 2012d, and a part of the fourth branch portion 2012f corresponding to the active layer 2011 separately become the gate 210 of the transistor.

It can be understood that the third branch portion 2012e can also defined between the second branch portion 2012d and the fourth branch portion 2012f. Optionally, the branch portion 2012b can extend from one side of the main stem portion 2012a, as shown in FIG. 2C-FIG. 2H. The branch portion 2012b can also extend from two sides of the main stem portion 2012a. The branch portion 2012b can also include sub-branch portions extending from each branch portion, and detailed description is omitted here.

Referring again to FIG. 2C-FIG. 2H, the display panel includes a plurality of the transistors, a plurality of the active layers 2011 of the transistors are spaced along the first direction x, a plurality of the branch portions 2012b of the gate layer 2012 of the transistors are spaced from one another, the main stem portion 2012a overlaps the active layers 2011 of the transistors at the overlapping area 200a, and the branch portion 2012b of each of the transistors correspondingly overlaps the active layers 2011 at the overlapping area 200a. That is, each main stem portion of a plurality of the gate layers 2012 sequentially extends in the first direction x to form a common main stem portion 2012a, the common main stem portion 2012a overlaps the active layer 2011 of the transistors at the overlapping area 200a, and the branch portion 2012b of the gate layer 2012 of each of the transistors correspondingly overlaps the active layers 2011 at the overlapping area 200a, to decease an area of the active layers 2011 occupied in the first direction x, facilitating increasing an aperture ratio of a pixel and realizing designs such as integration of sensing technology.

Referring again to FIG. 2B-FIG. 2H and FIG. 3A-FIG. 3C, the transistor further includes a second electrode 211 and a third electrode 212. In the top view, the second electrode 211 and the third electrode 212 are separately located on two sides of the gate 210. The active layer 2011 includes a channel region 2011a and a doped region 2011b located on two sides of the channel region 2011a. Wherein, the gate 210 corresponds to the channel region 2011a, and the second electrode 211 and the third electrode 212 separately correspond to the doped region 2011b. The second electrode 211 is one of a source or a drain, and the third electrode 212 is the other of the source or the drain.

Optionally, the second electrode 211 and the third electrode 212 can be directly formed by the doped region 2011b, and they can also be formed by electrodes electrically connected to the doped region 2011b. The doped region 2011b can include a p-type dopant or an n-type dopant to separately form a p-type active layer or an n-type active layer of the active layer 2011.

Furthermore, the doped region 2011b includes a lightly doped region 2011c located on two sides of the channel region 2011a and a heavily doped region 2011d located on one side of the lightly doped region 2011c away from the channel region 2011a, and the second electrode 211 and the third electrode 212 are directly formed by the heavily doped region 2011d. Specifically, as shown in FIG. 3A-FIG. 3C, the heavily doped region 2011d includes a first heavily doped region and a second heavily doped region, the first heavily doped region forms the second electrode 211, and the second heavily doped region forms the third electrode 212. Furthermore, the second electrode 211 is a source, and the third electrode 212 is a drain.

Still furthermore, in the top view, a width of the doped region 2011b is greater than or equal to a width of the channel region 2011a, facilitating a larger contact area of a signal line electrically connected to the active layer 2011, and ensuring connection reliability, as shown in FIG. 2B.

Referring again to FIG. 2A-FIG. 2H and FIG. 3A-FIG. 3C, the display panel 200 further includes a shading layer 202 located on one side of the active layer 2011 away from the gate layer 2012, and the shading layer 202 includes a shading portion 202a and a wiring portion 202b. Wherein, the shading portion 202a corresponds to the active layer 2011 to prevent the transistors from the effect of light that causes a problem of greater leakage current. The wiring portion 202b is electrically connected to the active layer 2011, and the wiring portion 202b forms a signal line to transmit a signal loaded therein to one of the second electrode 211 or the third electrode 212 of the transistor. Optionally, the signal line includes a data signal line for transmitting a data signal and/or a constant signal line for transmitting a constant signal, etc. The wiring portion 202b and the shading portion 202a can be directly connected, and they can also be spaced apart, as shown in FIG. 2A.

When the wiring portion 202b is directly connected to the shading portion 202a, on the one hand, the shading portion 202a can prevent the transistors from the effect of light that causes a problem of greater leakage current. On the other hand, the shading portion 202a can also collaboratively realize signal transmission with the wiring portion 202b, further decreasing the shading layer 202 affecting an aperture ratio of a pixel.

Furthermore, in the top view, the shading portion 202a is disposed corresponding to the channel region 2011a of the active layer 2011. Because the gate 210 corresponds to the channel region 2011a of the active layer 2011, a vertical projection of the overlapping area 200a on the shading portion 202a can be within boundaries of the shading portion 202a.

Referring again to FIG. 2A, the shading portion 202a can be square to realize an effective shading of the channel region 2011a. The shading portion 202a can also be an I shape to decrease the shading layer 202 affecting an aperture ratio of a pixel. Furthermore, a width and a length of the shading portion 202a can be decided according to a width and a length of the channel region 2011a. Specifically, the width of the shading portion 202a is greater or equal to the width of the channel region 2011b, and the length of the shading portion 202a is greater than or equal to the length of the channel region 2011a. Optionally, when the shading portion 202a is square, the width of the shading portion 202a can be greater than 6 micrometers, and the length of the shading portion 202a can be greater than 6.5 micrometers. Furthermore, the width of the shading portion 202a is equal to 8 micrometers, and the length of the shading portion 202a is equal 15 micrometers.

Because the wiring portion 202b is used for forming the signal line, a linewidth of the wiring portion 202b can be less than the width of the shading portion 202a, thereby further decreasing the shading layer 202 affecting an aperture ratio of a pixel. Specifically, the linewidth of the wiring portion 202b is equal to 2.5 micrometers. It can be understood that the width and the length of the shading portion 202a and the linewidth of the wiring portion 202b can be decided according to real circumstances, and detailed description is omitted here. Optionally, a manufacturing material of the shading layer 202 includes at least one of molybdenum, silver, aluminum, gold, etc. Furthermore, the manufacturing material of the shading layer 202 includes molybdenum/aluminum/molybdenum.

Referring again to FIG. 3A-FIG. 3C, the display panel 200 further includes a second electrode layer 203 and a third electrode layer 204. The active layer 2011 is electrically connected to the wiring portion 202b through the second electrode layer 203, while the third electrode layer 204 is located on one side of the gate layer 2012 away from the active layer 2011, and the third electrode layer 204 is electrically connected to the active layer 2011 to realize electrical connection between the wiring portion 202b and the active layer 2011 through the second electrode layer 204, so that a signal loaded into the signal line formed by the wiring portion 202b is transmitted to one of the second electrode 211 or the third electrode 212, and the signal is transmitted to the third electrode layer 204 through the active layer 2011 and the other of the second electrode 211 or the third electrode 212, to realize signal transmission.

Optionally, the third electrode layer 204 includes a pixel electrode. Furthermore, if the display panel 200 is a liquid crystal display panel, then the pixel electrode includes a single domain pixel structure and a multiple domain pixel structure. If the display panel 200 is a self-luminescence display panel, the display panel 200 includes a light-emitting device, and the light-emitting device includes an anode and a cathode, then the pixel electrode is one of the anode or the cathode. Furthermore, the pixel electrode is the anode of the light-emitting device.

In order to reduce manufacturing processes, the second electrode layer 203 is located at the same layer as the gate layer 2012, as shown in FIG. 3A. Furthermore, the second electrode layer 203 can also be located between the gate layer 2012 and the third electrode layer 204, as shown in FIG. 3B. Or the second electrode layer 203 is located between the active layer 2011 and the shading layer 202, as shown in FIG. 3C. Wherein, when the second electrode layer 203 is located between the active layer 2011 and the shading layer 202, the wiring portion 202b partially overlaps the doped region 2011b.

It can be understood that in the display panel as shown in FIG. 3A-FIG. 3C, a disposed position of the second electrode layer 203 can be designed with reference to each other. For example, in the display panel shown in FIG. 3C, the second electrode layer 203 can adopt the design in FIG. 3A, and detailed description is omitted here.

Referring again to FIG. 3A-FIG. 3C, the display panel 200 further includes a first substrate 214 and an insulating layer 213. The first substrate 214 is located on one side of the shading layer 202 away from the active layer 2011, and the insulating layer 213 includes a first insulating layer 2131, a second insulating layer 2132, and a third insulating layer 2133. The first insulating layer 2131 is located between the shading layer 202 and the active layer 2011, the second insulating layer 2132 is located between the active layer 2011 and the gate layer 2012, and the third insulating 2133 is located on one side of the gate layer 2012 away from the active layer 2011.

Wherein, the first insulating layer 2131, the second insulating layer 2132, and the third insulating 2133 include a via hole, and the third electrode layer 204 is electrically connected to the active layer 2011 through the via hole in the second insulating layer 2132 and the third insulating layer 2133.

The second electrode layer 203 can be electrically connected to the active layer 2011 and the shading layer 202 through the via hole in the first insulating layer 2131 and the second insulating layer 2132, as shown in FIG. 3A. Specifically, the via hole includes a first via hole 203a and a second via hole 203b spaced apart, and the second electrode layer 203 includes a first connecting part, a second connecting part, and a third connecting part electrically connected between the first connecting part and the second connecting part. Wherein, the first connecting part is in the first via hole 203a, the first connecting part is electrically connected to the active layer 2011, the second connecting part is in the second via hole 203b, and the second connecting part is electrically connected to the shading layer 202. Furthermore, the second electrode layer 203 is electrically connected to the active layer 2011 and the wiring portion 202b through the via hole in the first insulating layer 2131 and the second insulating layer 2132. Specifically, the via hole includes a first via hole 203a and a second via hole 203b spaced apart, and the second electrode layer 203 includes a first connecting part, a second connecting part, and a third connecting part electrically connected between the first connecting part and the second connecting part. Wherein, the first connecting part is in the first via hole 203a, the first connecting part is electrically connected to the active layer 2011, the second connecting part is in the second via hole 203b, and the second connecting part is electrically connected to the wiring portion 202b.

The second electrode layer 203 can also be electrically connected to the active layer 2011 and the shading layer 202 through the via hole in the first insulating layer 2131, the second insulating layer 2132, and the third insulating layer 2133, as shown in FIG. 3B. Specifically, the via hole includes a first via hole 203a and a second via hole 203b spaced apart, and the second electrode layer 203 includes a first connecting part, a second connecting part, and a third connecting part electrically connected between the first connecting part and the second connecting part. Wherein, the first connecting part is in the first via hole 203a, the first connecting part is electrically connected to the active layer 2011, the second connecting part is in the second via hole 203b, and the second connecting part is electrically connected to the shading layer 202. Furthermore, the second electrode layer 203 is electrically connected to the active layer 2011 and the wiring portion 202b through the via hole in the first insulating layer 2131, the second insulating layer 2132, and the third insulating layer 2133. Specifically, the via hole includes a first via hole 203a and a second via hole 203b spaced apart, and the second electrode layer 203 includes a first connecting part, a second connecting part, and a third connecting part electrically connected between the first connecting part and the second connecting part. Wherein, the first connecting part is in the first via hole 203a, the first connecting part is electrically connected to the active layer 2011, the second connecting part is in the second via hole 203b, and the second connecting part is electrically connected to the wiring portion 202b.

The second electrode layer 203 can also be electrically connected to the active layer 2011 and the shading layer 202 through the via hole in the first insulating layer 2131, as shown in FIG. 3C. Furthermore, the second electrode layer 203 is electrically connected to the active layer 2011 and the wiring portion 202b through the via hole in the first insulating layer 2131.

In order to prevent a sum of a depth of the via hole in the second insulating layer 2132 and the third insulating layer 2133 from being too great, leading to a problem of broken line of the third electrode layer 204 in the via hole, and a problem of contact resistance of the third electrode layer 204 and the active layer 2011, the display panel can also include a fourth electrode layer 205 and a planarization layer 215. The planarization layer 215 is located between the third electrode layer 204 and the fourth electrode layer 205, the fourth electrode layer 205 is located between the gate layer 2012 and the third electrode layer 204, and the third electrode layer 204 is electrically connected to the active layer 2011 through the fourth electrode layer 205. Specifically, the fourth electrode layer 205 is located between the planarization layer 215 and the third insulating layer 2133, the planarization layer 215 includes a via hole, the third electrode layer 204 is electrically connected to the fourth electrode layer 205 through the via hole in the planarization layer 215, and the fourth electrode layer 205 is electrically connected to the active layer 2011 through the via hole in the third insulating layer 2133 and the second insulating layer 2132, so that the third electrode layer 204 is electrically connected to the active layer 2011 through the fourth electrode layer 205. It can be understood that a structural schematic diagram of the display panel without the fourth electrode layer 205 can be implied with reference to the structural schematic diagrams of the display panels shown in FIG. 3A-FIG. 3C, and detailed description is omitted here.

Optionally, the second electrode layer 203 can include one of the second electrode 211 or the third electrode 212, and the fourth electrode layer 205 can include the other of the second electrode 211 or the third electrode 212.

Optionally, the insulating layer 213 includes at least one of an inorganic insulating layer or an organic insulating layer. A manufacturing material of the third electrode layer 204 is a transparent conducting material, the transparent conducting material includes oxide transparent conducting films, etc. The oxide transparent conducting films includes oxides of indium, tin, zinc, and cadmium and oxide thin film materials of their compounds, etc.

Referring again to FIG. 3A-FIG. 3C, the display panel further includes a fifth electrode layer 206. Wherein, if the display panel 200 is a liquid crystal display panel, then the fifth electrode layer 206 includes a common electrode, as shown in FIG. 3a-FIG. 3B. If the display panel 200 is a self-luminescence display panel, the display panel 200 includes a light-emitting device, the light-emitting device includes an anode and a cathode, then the fifth electrode layer 206 includes one of the anode or the cathode. Furthermore, the fifth electrode layer 206 includes the cathode of the light-emitting device, as shown in FIG. 3C.

Referring again to FIG. 3A-FIG. 3B, the display panel 200 includes liquid crystals 216, a second substrate 217, and sealant 207. Referring again to FIG. 3A, the fifth electrode layer 206 can be located on one side of the third electrode layer 204 close to the gate layer 2012, the liquid crystals 216 are located on one side of the third electrode layer 204 away from the fifth electrode layer 206, a protection layer 218 is disposed between the third electrode layer 204 and the fifth electrode layer 206 and on a surface of the third electrode layer 204 to make a pixel electrode and a common electrode be on the same substrate. Referring again to FIG. 3B, the fifth electrode layer 206 can also be located on one side of the third electrode layer 204 away from the gate layer 2012, the liquid crystals 216 are located between the third electrode layer 204 and the fifth electrode layer 206 to make a pixel electrode and a common electrode be on different substrates.

It can be understood that the display panel 200 shown in FIG. 3A-FIG. 3B can further include an alignment layer, a polarizer, a color filter, etc. that are not shown.

Referring again to FIG. 3C, when the display panel 200 is a self-luminescence display panel, the display panel 200 further includes a light-emitting layer 219 and a pixel definition layer 220. The light-emitting layer 219 is located between the third electrode layer 204 and the fifth electrode 206, and within a pixel definition area of the pixel definition layer 220.

It can be understood that the display panel 200 shown in FIG. 3C can further include a polarizer, a color filter, etc. that are not shown. Furthermore, the color filter includes a plurality of color filter units corresponding to the light-emitting device to increase a display effect of the display panel or to collaboratively realize a full color display of the display panel with the light-emitting device. Still furthermore, the light-emitting layer 219 and/or the color filter units can also include a quantum dot material, a perovskite material, a fluorescence material, etc. to collaboratively improve the display effect of the display panel with the display device.

Furthermore, the display panel according to embodiments of the present application further includes a touch control electrode, an encapsulation layer, etc. that are not shown.

The present application further provides a display device that includes any one of the above-described display panels.

Furthermore, the display device further includes a sensor to make the display device realize a design of sensing technology integration and realize functions such as fingerprint recognition, distance sensing, videoing, etc. Wherein, the sensor includes a photoelectric sensor, a distance sensor, an optical sensor, a camera, a gyro sensor, etc.

In the above-mentioned embodiments, description for each embodiment has different emphases, and contents not described in detail in one embodiment can be referred to relevant description of other embodiments. Detailed description of a display panel and a display device according to embodiments of the present application is given above. It should be understood that illustrative embodiments described above are descriptive, intended to facilitate understanding of the approach and main idea of the present application, and not intended to limit the present application. Description of features or aspects in each illustrative embodiment should generally be considered to apply to similar features or aspects of other illustrative embodiments. Although illustrative embodiments describe the present application, they can suggest to those skilled in the art making variations and modifications. The present application intends to include the variations and modifications within the scope of the appended claims, and many changes and modifications to the described embodiments can be carried out without departing from the scope and the spirit of the present application that is intended to be limited only by the appended claims.

What is claimed is:

1. A display panel, comprising a transistor, wherein the transistor comprises:
an active layer extending in a second direction; and
a gate layer located on one side of the active layer and comprising a main stem portion extending in a first direction and a branch portion extending from a side of the main stem portion;
wherein in a top view, the active layer overlaps the main stem portion and the branch portion at an overlapping area.

2. The display panel as claimed in claim 1, wherein the branch portion comprises:
a first branch portion extending from the side of the main stem portion in a direction away from the main stem portion; and
a second branch portion extending from one end of the first branch portion away from the main stem portion in a direction away from the first branch portion;
wherein the second branch portion overlaps the active layer at the overlapping area.

3. The display panel as claimed in claim 2, wherein the second branch portion is parallel to the main stem portion.

4. The display panel as claimed in claim 3, wherein a distance between the second branch portion and the main stem portion is greater than 3 micrometers.

5. The display panel as claimed in claim 2, wherein the branch portion comprises a third branch portion located between the first branch portion and the second branch portion.

6. The display panel as claimed in claim 1, comprising a plurality of the transistors, wherein a plurality of the active layers of the plurality of the transistors are spaced along the first direction, a plurality of the branch portions of the gate layer of the plurality of the transistors are spaced from one another, the main stem portion overlaps the active layers of the plurality of the transistors at the overlapping area, and the branch portion of each of the plurality of the transistors correspondingly overlaps the active layers at the overlapping area.

7. The display panel as claimed in claim 1, further comprising a shading layer located on one side of the active layer away from the gate layer, wherein the shading layer comprises a shading portion and a wiring portion, the shading portion corresponds to the active layer, and the wiring portion is electrically connected to the active layer.

8. The display panel as claimed in claim 7, further comprising:
a second electrode layer, wherein the active layer is electrically connected to the wiring portion through the second electrode layer; and
a third electrode layer located on one side of the gate layer away from the active layer and electrically connected to the active layer.

9. The display panel as claimed in claim 8, further comprising an insulating layer, wherein the insulating layer defines a via hole, and the second electrode layer is electrically connected to the active layer through the via hole.

10. The display panel as claimed in claim 9, wherein the insulating layer comprises a first insulating layer, the first insulating layer is located between the shading layer and the active layer, the first insulating layer defines the via hole, and the second electrode layer is electrically connected to the active layer and the wiring portion through the via hole in the first insulating layer.

11. The display panel as claimed in claim 9, wherein the via hole comprises a first via hole and a second via hole spaced apart, and the second electrode layer comprises a first connecting part, a second connecting part, and a third connecting part electrically connected between the first connecting part and the second connecting part, wherein, the first connecting part is in the first via hole, the first connecting part is electrically connected to the active layer, the second connecting part is in the second via hole, and the second connecting part is electrically connected to the wiring portion.

12. The display panel as claimed in claim 8, further comprising:
a fourth electrode layer located between the gate layer and the third electrode layer;
wherein the third electrode layer is electrically connected to the active layer through the fourth electrode layer.

13. The display panel as claimed in claim 12, comprising a fifth electrode layer located on one side of the third electrode layer.

14. The display panel as claimed in claim 7, wherein in the top view, the shading portion is a rectangle or an I shape.

15. The display panel as claimed in claim 1, wherein in the top view, the active layer is a straight line shape or an I shape, and the gate layer is an h shape, a Y shape, a Σ shape, or a Z shape.

16. The display panel as claimed in claim 1, wherein the active layer comprises a channel area and a doping area located on two sides of the channel area, and in the top view, a width of the doping area is greater than or equal to a width of the channel area.

17. A display device, comprising a display panel, wherein the display panel comprises a transistor, and the transistor comprises:
an active layer extending in a second direction; and
a gate layer located on one side of the active layer and comprising a main stem portion extending in a first direction and a branch portion extending from a side of the main stem portion;
wherein in a top view, the active layer overlaps the main stem portion and the branch portion at an overlapping area.

18. The display device as claimed in claim 17, wherein the branch portion comprises:
a first branch portion extending from the side of the main stem portion in a direction away from the main stem portion; and
a second branch portion extending from one end of the first branch portion away from the main stem portion in a direction away from the first branch portion;
wherein the second branch portion overlaps the active layer at the overlapping area.

19. The display device as claimed in claim 17, wherein the display panel comprises a plurality of the transistors, wherein a plurality of the active layers of the plurality of the transistors are spaced along the first direction, a plurality of the branch portions of the gate layer of the plurality of the transistors are spaced from one another, the main stem portion overlaps the active layers of the plurality of the transistors at the overlapping area, and the branch portion of each of the plurality of the transistors correspondingly overlaps the active layers at the overlapping area.

20. The display device as claimed in claim 17, wherein the display panel further comprises a shading layer located on one side of the active layer away from the gate layer, wherein the shading layer comprises a shading portion and a wiring portion, the shading portion corresponds to the active layer, and the wiring portion is electrically connected to the active layer.
